(19) United States
(12) Patent Application Publication
(10) Pub. No.: US 2021/0043872 A1
(43) Pub. Date: Feb. 11, 2021

(54) DISPLAY PANEL, DISPLAY DEVICE AND METHOD FOR MANUFACTURING THE SAME

(71) Applicants: Hefei Xinsheng Optoelectronics Technology Co., Ltd., Hefei (CN); BOE TECHNOLOGY GROUP CO., LTD., Beijing (CN)

(72) Inventor: Xinwei GAO, Beijing (CN)

(21) Appl. No.: 16/939,155

(22) Filed: Jul. 27, 2020

(30) Foreign Application Priority Data
Aug. 7, 2019 (CN) 201910726689.9

(51) Int. Cl. H01L 51/52; H01L 27/32; H01L 51/56

(52) U.S. Cl. CPC H01L 51/5253; H01L 2227/323; H01L 51/56; H01L 27/3246

(57) ABSTRACT

The present disclosure discloses a display panel, a display device, and a method for manufacturing the same, which solves the problem of special-shaped OLED display panels being prone to moisture intrusion from its edge. A display panel is provided that includes a base substrate, a thin film transistor, a planarization layer, a first electrode layer, a pixel definition layer, a partition layer, an electroluminescent device organic layer, a second electrode layer, an encapsulation layer, an encapsulation glue, and an encapsulation cover plate, where the partition layer is disposed at the edge of the electroluminescent device organic layer, contacts with the encapsulation layer, and partitions the electroluminescent device organic layer at its edge.

### CROSS REFERENCE TO RELATED APPLICATION

This application is based upon, claims the benefit of, and claims priority to Chinese Patent Application No. 201910726689.9, filed on Aug. 7, 2019, the entire contents thereof being incorporated by reference herein.

### TECHNICAL FIELD

The present disclosure relates to display device technology and more particularly, to a display panel, a display device, and a method for manufacturing the same.

### BACKGROUND

With the advancement of display technology, special-shaped display products have been rapidly applied and promoted. The special-shaped display products usually use special-shaped display panels, where all or part of edges of which are arc-shaped and organic light-emitting (OLED) special-shaped display panels are the most popular. The special-shaped OLED display panel needs to perform evaporation of an electroluminescent device organic layer with the cooperation of a mask plate to form a main display area during production.

However, the mask plate is generally rectangular. For a display panel where all or part of edges of which are arc-shaped, an electroluminescent device organic layer will be left on the arc-shaped edges. Moreover, since the electroluminescent device organic layer is made of an organic material, its film layer is loose making it easy for moisture and oxygen to penetrate, therefore, moisture enters and penetrates from the electroluminescent device organic layer at the arc-shaped edges to interior, resulting in that the display panel neither emits light nor displays.

### SUMMARY

In view of the above, embodiments of the present disclosure provide a display panel, a display device, and a method for manufacturing the same that solves the problem that, during the manufacturing of a special-shaped OLED display panel, the special-shaped OLED display panel is prone to moisture intrusion from the edge after it is cut due to the limitation of a mask plate, resulting in that the display panel neither emits light nor displays.

To achieve the above purpose, the present disclosure mainly provides the following technical solutions:

On one hand, an embodiment of the present disclosure provides a display panel including a display area and a frame area; and including a base substrate, an insulating layer, a thin film transistor, a planarization layer, a first electrode layer, a pixel definition layer, an electroluminescent device organic layer, a second electrode layer, an encapsulation layer, an encapsulation glue and an encapsulation cover plate, wherein the display panel further includes:

a partition layer disposed in the frame area, and corresponding to an edge of the electroluminescent device organic layer, wherein the electroluminescent device organic layer is disposed on a side of the partition layer distal to the base substrate, the partition layer contacts the encapsulation layer and is disposed between the encapsulation layer and the base substrate, and the partition layer is configured to divide the electroluminescent device organic layer into two discontinuous parts in the frame area, and the encapsulation layer is disposed between the two discontinuous parts.

The purpose of the present disclosure may be further achieved and its technical problem may be solved by adopting the following technical measures.

Optionally, in the aforementioned display panel, an outer edge of the partition layer inclines toward the electroluminescent device organic layer in the display area of the display panel in a direction from a level distal to the base substrate to a level close to the base substrate, and the encapsulation layer contacts the outer edge of the partition layer, wherein the outer edge of the partition layer faces the frame area of the display panel.

Optionally, in the aforementioned display panel, an inner edge of the partition layer inclines toward the electroluminescent device organic layer in the display area of the display panel in a direction from a level distal to the base substrate to a level close to the base substrate, and the electroluminescent device organic layer contacts the inner edge of the partition layer, wherein the inner edge of the partition layer faces the display area of the display panel.

Optionally, in the aforementioned display panel, an inner edge of the partition layer is disposed in a vertical direction or in a direction parallel to an outer edge of the partition layer, and contacts the electroluminescent device organic layer, wherein the inner edge of the partition layer faces the display area of the display panel, and the outer edge of the partition layer faces the frame area of the display panel.

Optionally, in the aforementioned display panel, an inner edge of the partition layer is disposed in a vertical direction or in a direction parallel to the outer edge of the partition layer, and contacts the electroluminescent device organic layer, wherein the inner edge of the partition layer faces the display area of the display panel.

Optionally, in the aforementioned display panel, the partition layer includes a first partition layer and a second partition layer, and the first partition layer and the second partition layer are adjacent to and contact each other in a direction parallel the base substrate, and

an outer edge of the first partition layer inclines toward the electroluminescent device organic layer in the display area of the display panel in a direction from a level distal to the base substrate to a level close to the base substrate, and contacts the encapsulation layer; and an inner edge of the second partition layer is disposed in a vertical direction or in a direction parallel to the outer edge of the first partition layer, and contacts the electroluminescent device organic layer, wherein the outer edge of the first partition layer faces the frame area of the display panel, and the inner edge of the second partition layer faces the display area of the display panel.

Optionally, in the aforementioned display panel, a cross-section of the first partition layer is an inverted trapezoid, and a cross-section of the second partition layer is a normal trapezoid.

Optionally, in the aforementioned display panel, each of a cross-section of the first partition layer and a cross-section of the second partition layer is a parallelograms.

Optionally, in the aforementioned display panel, edges of the first partition layer and the second partition layer that contact each other are vertically arranged.

Optionally, in the aforementioned display panel, the first partition layer and the second partition layer have different heights with respect to the base substrate.

Optionally, in the aforementioned display panel, the height of the first partition layer with respect to the base substrate is larger than that of the second partition layer.

Optionally, in the aforementioned display panel, material for forming the first partition layer is a negative photoresist, and material for forming the second partition layer and the pixel definition layer is a positive photoresist.

Optionally, in the aforementioned display panel, the second electrode layer is located between the electroluminescent device organic layer and the encapsulation layer, the partition layer is configured to divide the second electrode layer into two discontinuous parts in the frame area, and the encapsulation layer is disposed between the two discontinuous parts.

Optionally, in the aforementioned display panel, the display panel includes a plurality of the partition layers, the plurality of partition layers are arranged to be adjacent to each other in sequence in a direction parallel the base substrate, and the adjacent partition layers are spaced apart by a predetermined distance.

Optionally, in the aforementioned display panel, the display panel is special-shaped OLED display panel.

On the other hand, an embodiment of the present disclosure provides a display device, including any one of the aforementioned display panels.

Further, on the other hand, an embodiment of the present disclosure provides a method for manufacturing a display panel, wherein the display panel includes a display area and a frame area; and includes a base substrate, an insulating layer, a thin film transistor, a planarization layer, a first electrode layer, a pixel definition layer, a partition layer, an electroluminescent device organic layer, a second electrode layer, an encapsulation layer, an encapsulation glue and an encapsulation cover plate, and the method includes:

manufacturing the thin film transistor, the planarization layer and the first electrode layer on the base substrate;

manufacturing the pixel definition layer and the partition layer on a side of the first electrode layer distal to the base substrate, wherein the partition layer is disposed in the frame area;

manufacturing the electroluminescent device organic layer and the second electrode layer on a side of the partition layer distal to the base substrate, wherein the partition layer corresponds to an edge of the electroluminescent device organic layer;

manufacturing the encapsulation layer on a side of the second electrode layer distal to the base substrate, wherein the partition layer contacts the encapsulation layer and is disposed between the encapsulation layer and the base substrate, and the partition layer is configured to divide the electroluminescent device organic layer into two discontinuous parts in the frame area, and the encapsulation layer is disposed between the two discontinuous parts; and

completing encapsulation and performing special-shaped cutting.

Optionally, the step of manufacturing the pixel definition layer and the partition layer on a side of the first electrode layer distal to the base substrate includes:

obtaining the pixel definition layer by coating a photoresist, curing, exposure, and development in sequence.

Optionally, the step of obtaining the pixel definition layer by coating a photoresist, curing, exposure, and development in sequence includes:

obstructing a positive photoresist in the frame area of the display panel during the exposure to obtain the second partition layer.

Optionally, the step of manufacturing the pixel definition layer and the partition layer on a side of the first electrode layer distal to the base substrate includes:

obtaining the first partition layer by coating a photoresist, curing, exposure, and development in sequence.

With the above technical solutions, the display panel, display device, and method for manufacturing the same of the present disclosure have at least the following advantages: in order to solve the problem that, during the manufacturing of a special-shaped OLED display panel, the special-shaped OLED display panel is prone to moisture intrusion from the edge after it is cut due to the limitation of a mask plate, resulting in that the display panel neither emits light nor displays, in the display panel provided by the present disclosure, the partition layer is provided at the edge of the electroluminescent device organic layer, to partition the electroluminescent device organic layer, thus preventing moisture from intruding into the inside of the display panel through the electroluminescent device organic layer. In addition, the encapsulation layer contacts the partition layer at the partition point of the electroluminescent device organic layer, keeps its morphology intact, and further blocks the external moisture, thus improving the encapsulation effect of the special-shaped OLED display panel, and increasing the service life of the display panel.

### BRIEF DESCRIPTION OF THE DRAWINGS

FIG. 1 is a schematic structural diagram of a display panel according to an embodiment of the present disclosure;

FIG. 2 is a schematic structural diagram of a portion of a display panel according to an embodiment of the present disclosure;

FIG. 3 is a schematic structural diagram of a portion of a display panel according to another embodiment of the present disclosure;

FIG. 4 is a schematic structural diagram of an electroluminescent device organic layer in a display panel according to an embodiment of the present disclosure; and

FIG. 5 is a flowchart of a method of manufacturing a display panel according to an embodiment of the present disclosure.

### DETAILED DESCRIPTION

In order to further describe the technical means and effect of the present disclosure to achieve the intended objective of the invention, hereinafter, a display panel, a display device and a method for manufacturing the same provided by the present disclosure, and detailed implementation manners, structures, features and effects thereof will be described in detail in conjunction with the drawings and preferred embodiments. In the following description, different “an embodiment” or “embodiment” does not necessarily refer to the same embodiment. In addition, specific features, structures, or characteristics in one or more embodiments may be combined in any suitable form.

The technical solutions of the embodiments of the present disclosure have the following general idea to solve the above technical problem.

### Embodiment 1

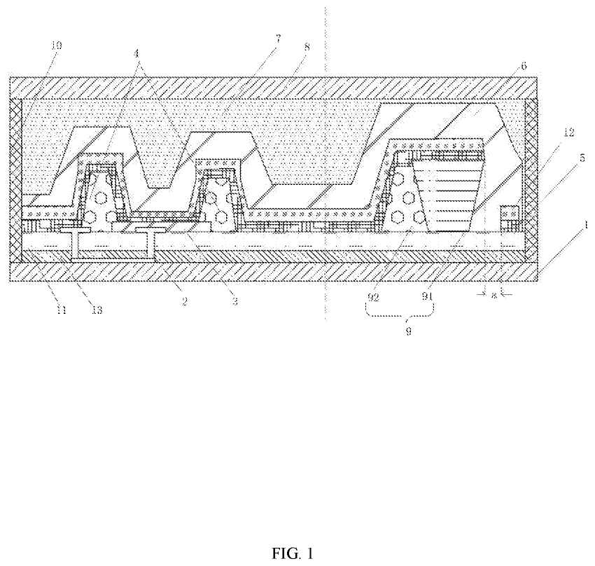

Referring to FIG. 1, a display panel provided by an embodiment of the present disclosure includes a display area and a frame area, and includes a base substrate 1, an insulating layer 13, a thin film transistor 2, a planarization layer 11, a first electrode layer 3, a pixel definition layer 4, an electroluminescent device organic layer 5, a second electrode layer 12, an encapsulation layer 6, an encapsulation glue 7 and an encapsulation cover plate 8.

The display panel further includes a partition layer 9 disposed in the frame area, and corresponding to the edge of the electroluminescent device organic layer 5. The electroluminescent device organic layer 5 is disposed on a side of the partition layer 9 distal to the base substrate 1. The partition layer 9 contacts the encapsulation layer 6 and is disposed between the encapsulation layer 6 and the base substrate 1, and is configured to divide the electroluminescent device organic layer 5 into two discontinuous (inner and outer) parts in the frame area, and the encapsulation layer 6 is disposed between the two discontinuous parts. Here, the said frame area of the display panel refers to an area close to the frame of the display panel and not used for emitting light and displaying of the display panel.

Specifically, in order to solve the problem that, during the manufacturing of a special-shaped OLED display panel, the special-shaped OLED display panel is prone to moisture intrusion from the edge after it is cut due to the limitation of a mask plate, resulting in that the display panel neither emits light nor displays, embodiments of the present disclosure provide a display panel. That is to say, the present disclosure is mainly directed to a special-shaped OLED display panel. Referring to FIG. 1, for example, a light-emitting display area of the entire display panel is shown on the left side of the longest vertical dotted line, and the frame area of the entire display panel is shown on the right side of the vertical dotted line. The main technical solution of the present disclosure is that the partition layer 9 is disposed at the edge of the electroluminescent device organic layer 5 in the frame area (for example, the right side of vertical dotted line shown in the figures), i.e., disposed at the electroluminescent device organic layer 5 in the frame area, to partition the electroluminescent device organic layer 5 in the frame area. That is to say, the electroluminescent device organic layer 5 is partitioned into inner and outer portions. Furthermore, the encapsulation layer 6 separates the inner and outer portions of the electroluminescent device organic layer 5 at the partition point and contacts the partition layer 9, to ensure that when external moisture intrudes into the electroluminescent device organic layer 5 at the edge (for example, the right side), i.e., in the frame area of the overall display panel, it can only intrude into the electroluminescent device organic layer 5 located close to the outer side of the display panel, but cannot intrude into the electroluminescent device organic layer 5, which is separated by the encapsulation layer 6, located close to the inner side of the display panel, due to the partition of the encapsulation layer 6. That is to say, the partitioned portion can block the moisture. Moreover, there is generally no morphology change in the layer structure of the encapsulation layer 6, which does not produce any effect on the manufacturing of other films thereon or on the encapsulation. The partition layer 9 is made of an organic photoresist. The encapsulation layer 6 is made of an inorganic material. The electroluminescent device organic layer 5 is adjacent to and contacts the second electrode layer 12.

The electroluminescent device organic layer 5 contacts the pixel definition layer 4. The second electrode layer 12 is disposed between the electroluminescent organic layer 5 and the encapsulation layer 6 and contacts the encapsulation layer 6. That is to say, the electroluminescent organic layer 5 is below the second electrode layer 12. The partition layer 9 divides the second electrode layer 12 into two discontinuous (inner and outer) parts in the frame area of the display panel, and the encapsulation layer 6 is disposed between the two discontinuous parts.

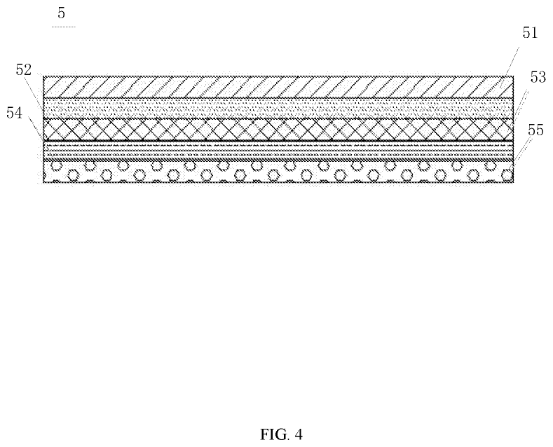

Referring to FIG. 4, the electroluminescent device organic layer 5 includes a hole injection layer 51, a hole transport layer 52, a light emitting layer 53, an electron transport layer 54 and an electron injection layer 55 which are stacked in sequence. The hole injection layer 51 is adjacent to the first electrode layer 3 and the electron injection layer 55 is adjacent to the second electrode layer 12. This structure is well known to those skilled in the art in the art, which will not be elaborated here.

According to the above listed, the display panel, display device and manufacturing method of the present disclosure have at least the following advantages: in the display panel provided by the present disclosure, the partition layer 9 is provided at the edge of the electroluminescent device organic layer 5, to partition the electroluminescent device organic layer 5, thus preventing moisture from intruding into the inside of the display panel through the electroluminescent device organic layer 5; in addition, the encapsulation layer 6 contacts the partition layer 9 at the partition point of the electroluminescent device organic layer 5, keeps its morphology intact, and further blocks the external moisture, thus improving the encapsulation effect of the special-shaped OLED display panel, and increasing the service life of the display panel.

Further, referring to FIG. 1, in the display panel provided by the embodiment of the present disclosure, an outer edge (side) of the partition layer 9 inclines toward the electroluminescent device organic layer 5 in the display area of the display panel in a direction from a level distal to the base substrate 1 to a level close to the base substrate 1, and the encapsulation layer 6 completely contacts the outer edge of the partition layer 9. Hereinafter, the outer edge of the partition layer 9 faces the frame area of the display panel.

Specifically, in order to realize that the partition layer 9 can divide the electroluminescent device organic layer 5 into the inner and outer portions, and that the encapsulation layer 6 can block the inner and outer portions of the electroluminescent device organic layer 5, in the technical solution adopted by the present disclosure, the outer edge of the partition layer 9, i.e., the outer side thereof in the frame area is set to be inclined, and the outer edge of the partition layer 9 completely contacts the encapsulation layer 6. The inclination direction of the outer edge of the partition layer 9 depends on the fact that the electroluminescent device organic layer 5 is physically deposited during the manufacturing, and the organic material is deposited from bottom to top. That is to say, in order to divide the electroluminescent device organic layer 5 into the inner and outer portions, referring to FIG. 1, when the electroluminescent device organic layer 5 is deposited, there is at least a certain width a, within which the organic material cannot deposit upwards since deposition is obstructed during upward deposition, so the electroluminescent device organic layer 5 will not be formed there. The technical solution adopted by the present disclosure is to set the inclination direction of the outer edge of the partition layer 9 as inclining from the top surface of the partition layer 9 to the bottom surface of the partition layer 9 (i.e., in a direction from the level distal to the base substrate 1 to the level close to the base substrate 1) to the light-emitting display area for example shown on the left side of the aforesaid vertical dotted line, which can produce the technical effect of inducing a width difference of the outer edge of the partition layer 9 between the top surface and the bottom surface of the partition layer 9. That is to say, the projection of the outer edge of the partition layer 9 at the top surface thereof in a direction perpendicular to the base substrate 1 completely covers and is larger than the projection of the outer edge of the partition layer 9 at the bottom surface thereof in a direction perpendicular to the base substrate 1, so that the organic material at least within the width a is hindered by the inclined outer edge of the partition layer 9 during the upward deposition. That is to say, it make that the electroluminescent device organic layer 5 on the outer side of the partition layer 9 can only deposit upwards on the right side of the aforesaid width a, and electroluminescent device organic layer 5 being continuous with the top surface (upper side) of the partition layer 9 cannot be formed within the width a. The deposition of the electroluminescent device organic layer 5 on the upper side of the partition layer 9 will not be affected, therefore, the electroluminescent device organic layer 5 is divided into two parts on the left and right sides of the width a. Further, the encapsulation layer 6 is formed by a chemical vapor deposition method above the electroluminescent device organic layer 5, and can diffuse to the gaps or holes and fill the gaps or holes perfectly. Therefore, the encapsulation layer 6 can be formed on the upper side of the electroluminescent device organic layer 5 and completely contact the inclined outer edge of the partition layer 9 at the width a, to completely separate the two parts of the electroluminescent device organic layer 5.

Term “and/or” used herein only refers to an association relationship that describes associated objects, which represents that there may be three relationships, taking A and/or B as an example, it can be specifically understood as that both A and B may be included simultaneously, or, A or B may exist alone, it may be any one of the above-mentioned three situations.

Further, an embodiment of the present disclosure provides a display panel. In a specific implementation, an inner edge (side) of the partition layer 9 inclines toward the electroluminescent device organic layer 5 in the display area of the display panel in a direction from a level distal to the base substrate 1 to a level close to the base substrate 1, and the electroluminescent device organic layer 5 completely contacts the inner edge of the partition layer 9. Hereinafter, the inner edge of the partition layer 9 faces the display area of the display panel.

Further, an embodiment of the present disclosure provides a display panel. In a specific implementation, an inner edge of the partition layer 9 is disposed in a vertical direction or in a direction parallel to the outer edge of the partition layer 9, and completely contacts the electroluminescent device organic layer 5.

Specifically, in order to improve the partition layer 9 and prevent gaps presented on the inner side of the partition layer 9 resulting in that the encapsulation layer 6 completely loses the effect of separation, in the technical solution adopted by the present disclosure, the inner edge of the partition layer 9 is set as a vertical straight side or an inclined side parallel to the outer edge of the partition layer 9, that is, a cross-section of the partition layer 9 may be an inverted right-angle trapezoid or a parallelogram. It needs to ensure that the inner edge of the partition layer 9 completely contacts the electroluminescent device organic layer 5. Although the encapsulation layer 6 can fill the gaps or holes when it is manufactured by chemical vapor deposition, the filling may be not perfect. If the inner edge of the partition layer 9 is set in an inclination direction opposite to its outer edge, for example, the partition layer 9 is set as an inverted isosceles trapezoid, both the inner and outer sides of the partition layer 9 will partition the electroluminescent device organic layer 5. However, if the filling of the encapsulation layer 6 is not good when it is formed, there may be gaps on the inner side and/or outer side of the partition layer 9, which causes that the obstruction of the moisture completely fails. Therefore, it needs to ensure that the electroluminescent device organic layer 5 is not partitioned on the inner side of the partition layer 9, which can partially obstruct the moisture. It should be noted that, in an ideal condition, the inner edge of the partition layer 9 may be set in an inclination direction opposite to the outer edge of the partition layer 9 as well, for example, the partition layer 9 is an inverted isosceles trapezoid, then the inner edge of the partition layer 9 will divide the electroluminescent device organic layer 5 into two parts as well, but it must ensure that the encapsulation layer 6 can perfectly fill the gaps and holes, thus it can further block the moisture.

### Embodiment 2

Further, referring to FIG. 1, an embodiment of the present disclosure provides a display panel. In a specific implementation, the partition layer 9 includes a first partition layer 91 and a second partition layer 92, and the first partition layer 91 and the second partition layer 92 are adjacent to and contact each other in a direction parallel the base substrate 1, i.e. from outer to inner of the display panel.

An outer edge (side) of the first partition layer 91 inclines toward the electroluminescent device organic layer 5 in the display area of the display panel in a direction from a level distal to the base substrate 1 to a level close to the base substrate 1, and contacts the encapsulation layer 6. An inner edge of the second partition layer 92 is disposed in a vertical direction or in a direction parallel to the outer edge of the first partition layer 91, and completely contacts the electroluminescent device organic layer 5. Hereinafter, the outer edge of the first partition layer 91 faces the frame area of the display panel, and the inner edge of the second partition layer 92 faces the display area of the display panel.

Specifically, in order to enrich the partition layer 9 and simplify the manufacturing method thereof, in the technical solution adopted by the present disclosure, the partition layer 9 is arranged as that the first partition layer 91 and the second partition layer 92 are adjacent to and contact each other in a direction parallel the base substrate 1, i.e. from outer to inner of the display panel. The first partition layer 91 is closer to the outer side of the display panel than the second partition layer 92, so the outer edge of the first partition layer 91 needs to be obliquely disposed as the outer edge of the partition layer 9 mentioned above, and the second partition layer 92 is located on the inner side of the he second partition layer 92. The material for forming the first partition layer 91 is a negative photoresist. The material for forming the second partition layer 92 is a positive photoresist, which is the same as the material for forming the pixel definition layer 4. It should be noted that the second partition layer 92 and the pixel definition layer 4 may be simultaneously manufactured, which greatly simplifies the manufacturing processes and technological processes.

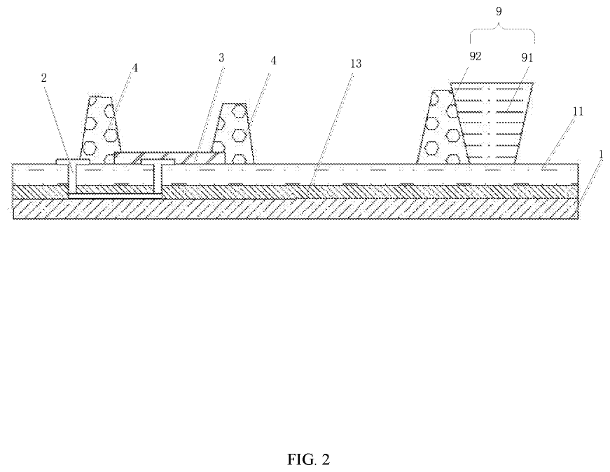

Further, referring to the FIGS. 1-3, a cross-section of the first partition layer 91 is an inverted trapezoid, and a cross-section of the second partition layer 92 is a normal trapezoid.

Specifically, in order to ensure perfect contact between the first partition layer 91 and the second partition layer 92, in the technical solution adopted by the present disclosure, the first partition layer 91 is set as an inverted trapezoid, and the second partition layer 92 is set as a normal trapezoidal, and their edges that are connected to each other or contact each other are provided to mutually fit inclination direction. It should be noted that the edges of the first partition layer 91 and the second partition layer 92 that are connected to each other or contact each other may be vertically arranged. That is to say, they are two right-angle trapezoid respectively being normal inverted, or two parallelograms, which will not be elaborated here, as long as the outermost edge is inclined toward the inner side of the display panel from top to bottom of the partition layer 9, and the innermost edge is referred to the above-mentioned embodiments.

As an embodiment of the present disclose, as shown in FIGS. 1-3, the first partition layer 91 and the second partition layer 92 may have different heights with respect to the base substrate 1.

As an embodiment of the present disclose, as shown in FIGS. 1-3, the height of the first partition layer 91 with respect to the base substrate 1 is larger than that of the second partition layer 92.

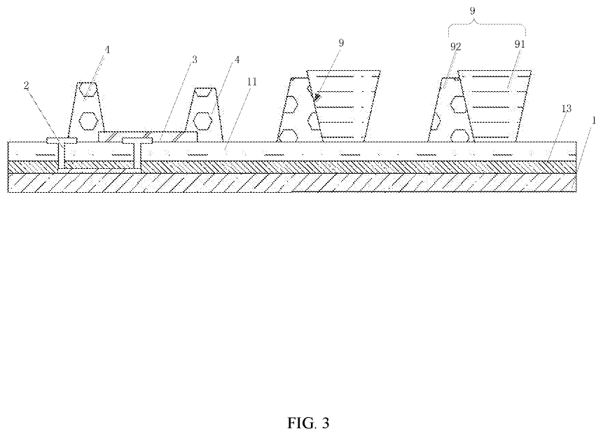

Further, referring to FIG. 3, an embodiment of the present disclosure provides a display panel including a plurality of the aforesaid partition layers 9, wherein the plurality of partition layers 9 are arranged to be adjacent to each other in sequence in a direction parallel the base substrate 1, i.e. from outer to inner of the display panel, and the adjacent partition layers 9 are spaced apart by a predetermined distance.

Specifically, in order to ensure the blocking effect of the partition layer 9, in the technical solution adopted by the present disclosure, a plurality of partition layers 9 are provided in the frame area of the overall display panel in sequence, to separate and block the electroluminescent device organic layer 5 many times, thus further ensuring that the external moisture cannot intrude into the light-emitting display area of the entire display panel.

### Embodiment 3

Further, an embodiment of the present disclosure provides a display device, which includes the display panel described in the above-mentioned embodiments.

It can be understood that, the display panel in this embodiment may directly adopt the display panel obtained in any one or a combination of Embodiments 1-2, the specific structure of which can be referred to the content of the foregoing embodiments.

### Embodiment 4

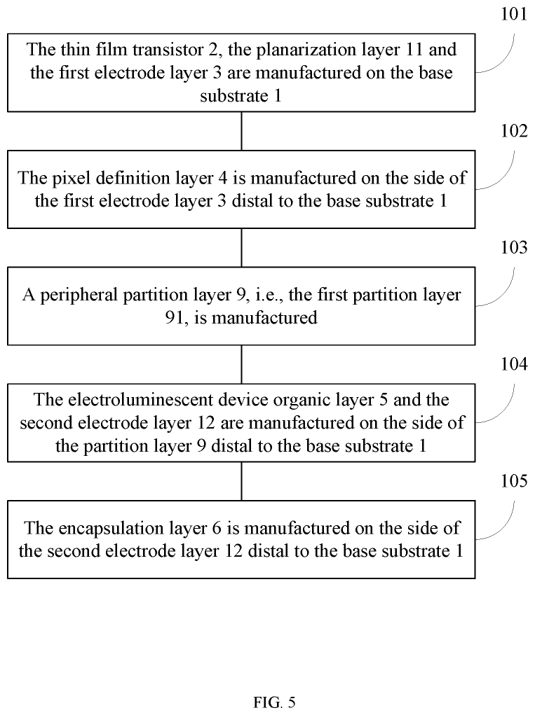

An embodiment of the present disclosure further provides a method for manufacturing the display panel according to Embodiments 1-2. FIG. 5 is a flowchart of a method of manufacturing a display panel according to an embodiment of the present disclosure. As shown in FIG. 5, the method includes the following steps 101-106.

In step 101, the thin film transistor 2, the planarization layer 11 and the first electrode layer 3 are manufactured on the base substrate 1.

Specifically, the thin film transistor (TFT) circuit 2 and the first electrode layer 3 of indium tin oxide (ITO) are manufactured on the base substrate 1.

In step 102, the pixel definition layer 4 is manufactured on the side of the first electrode layer 3 distal to the base substrate 1.

Specifically, the pixel definition layer 4 of the light-emitting display area of the display panel is obtained by coating a photoresist (a positive photoresist as the pixel definition layer 4), curing, exposure, and development in sequence.

If the second partition layer 92 is present, the method further includes obstructing the positive photoresist in the frame area of the display panel during the exposure process to obtain the second partition layer 92.

In step 103, a peripheral partition layer 9, i.e., the first partition layer 91, is manufactured.

Specifically, the first partition layer 91 in the frame area is obtained by coating a photoresist (a negative photoresist as the first partition layer 91), curing, exposure, and development in sequence.

The partition layer 9 (including the first partition layer 91 and the second partition layer 92) is disposed in the frame area.

In step 104, the electroluminescent device organic layer 5 and the second electrode layer 12 are manufactured on the side of the partition layer 9 distal to the base substrate 1. The partition layer 9 corresponds to the edge of the electroluminescent device organic layer 5.

Specifically, the electroluminescent device organic layer 5, i.e., an electroluminescent (EL) device organic layer, is manufactured by inkjet printing or evaporation.

The second electrode layer 12, i.e., an electroluminescent (EL) device cathode layer, is manufactured by magnetron sputtering or evaporation.

In step 105, the encapsulation layer 6 is manufactured on the side of the second electrode layer 12 distal to the base substrate 1.

Specifically, the encapsulation layer 6 is manufactured by chemical vapor deposition (CVD), atomic layer deposition (ALD), or magnetron sputtering (Sputter).

The partition layer 9 contacts the encapsulation layer 6 and is disposed between the encapsulation layer 6 and the base substrate 1, and is configured to divide the electroluminescent device organic layer 5 into two discontinuous (inner and outer) parts in the frame area, and the encapsulation layer 6 is disposed between the two discontinuous parts.

In step 106, encapsulation is completed and special-shaped cutting is performed.

Specifically, referring to FIG. 1, a dam 10 is provided in the periphery of the base substrate 1, such that the base substrate 1 and the dam 10 form a structure with a top open. Further, filler is filled on the encapsulation layer 6 to form encapsulation glue 7. Moreover, an encapsulation cover plate 8 is finally attached onto the encapsulation glue 7 by lamination, to complete the encapsulation of the overall display panel. Finally, special-shaped cutting is performed as needed to form a special-shaped OLED display panel.

It should be noted that the above described is only preferred embodiment of the present disclosure, and does not limit the present disclosure in any form, so the above-mentioned embodiments can be combined. Any simple variations, equivalent changes and modifications of the above-described embodiments made based on the technical essence of the present disclosure are within the scope of the technical solution of the present disclosure.

What is claimed is:

1. A display panel, comprising:
a display area, a frame area, a base substrate, an insulating layer, a thin film transistor, a planarization layer, a first electrode layer, a pixel definition layer, an electroluminescent device organic layer, a second electrode layer, an encapsulation layer, an encapsulation glue, and an encapsulation cover plate; and
a partition layer disposed in the frame area, and corresponding to an edge of the electroluminescent device organic layer, wherein the electroluminescent device organic layer is disposed on a side of the partition layer distal to the base substrate, the partition layer contacts the encapsulation layer and is disposed between the encapsulation layer and the base substrate, the partition layer is configured to divide the electroluminescent device organic layer into two discontinuous parts in the frame area, and the encapsulation layer is disposed between the two discontinuous parts.

2. The display panel according to claim 1, wherein:
an outer edge of the partition layer inclines toward the electroluminescent device organic layer in the display area of the display panel in a direction from a level distal to the base substrate to a level close to the base substrate; and
the encapsulation layer contacts the outer edge of the partition layer, wherein the outer edge of the partition layer faces the frame area of the display panel.

3. The display panel according to claim 1, wherein:
an inner edge of the partition layer inclines toward the electroluminescent device organic layer in the display area of the display panel in a direction from a level distal to the base substrate to a level close to the base substrate; and
the electroluminescent device organic layer contacts the inner edge of the partition layer, wherein the inner edge of the partition layer faces the display area of the display panel.

4. The display panel according to claim 1, wherein:
an inner edge of the partition layer is disposed in a vertical direction or in a direction parallel to an outer edge of the partition layer, and contacts the electroluminescent device organic layer; and
the inner edge of the partition layer faces the display area of the display panel, and the outer edge of the partition layer faces the frame area of the display panel.

5. The display panel according to claim 2, wherein:
an inner edge of the partition layer is disposed in a vertical direction or in a direction parallel to the outer edge of the partition layer; and
contacts the electroluminescent device organic layer, wherein the inner edge of the partition layer faces the display area of the display panel.

6. The display panel according to claim 5, wherein:
the partition layer comprises a first partition layer and a second partition layer, and the first partition layer and the second partition layer are adjacent to and contact each other in a direction parallel the base substrate; and
an outer edge of the first partition layer inclines toward the electroluminescent device organic layer in the display area of the display panel in a direction from a level distal to the base substrate to a level close to the base substrate, and contacts the encapsulation layer; and an inner edge of the second partition layer is disposed in a vertical direction or in a direction parallel to the outer edge of the first partition layer, and contacts the electroluminescent device organic layer, wherein the outer edge of the first partition layer faces the frame area of the display panel, and the inner edge of the second partition layer faces the display area of the display panel.

7. The display panel according to claim 6, wherein a cross-section of the first partition layer is an inverted trapezoid, and a cross-section of the second partition layer is a normal trapezoid.

8. The display panel according to claim 6, wherein each of a cross-section of the first partition layer and a cross-section of the second partition layer is a parallelograms.

9. The display panel according to claim 7, wherein edges of the first partition layer and the second partition layer that contact each other are vertically arranged.

10. The display panel according to claim 6, wherein the first partition layer and the second partition layer have different heights with respect to the base substrate.

11. The display panel according to claim 10, wherein the height of the first partition layer with respect to the base substrate is larger than that of the second partition layer.

12. The display panel according to claim 6, wherein material for forming the first partition layer is a negative photoresist, and material for forming the second partition layer and the pixel definition layer is a positive photoresist.

13. The display panel according to claim 1, wherein:
the second electrode layer is located between the electroluminescent device organic layer and the encapsulation layer;
the partition layer is configured to divide the second electrode layer into two discontinuous parts in the frame area; and
the encapsulation layer is disposed between the two discontinuous parts.

14. The display panel according to claim 1, wherein the display panel comprises a plurality of the partition layers, the plurality of partition layers are arranged to be adjacent to each other in sequence in a direction parallel the base substrate, and the adjacent partition layers are spaced apart by a predetermined distance.

15. The display panel according to claim 1, wherein the display panel is special-shaped organic light-emitting diode (OLED) display panel.

16. A display device, comprising:
a display panel, comprising:
a display area, a frame area, a base substrate, an insulating layer, a thin film transistor, a planarization layer, a first electrode layer, a pixel definition layer, an electroluminescent device organic layer, a second electrode layer, an encapsulation layer, an encapsulation glue, and an encapsulation cover plate; and
a partition layer disposed in the frame area, and corresponding to an edge of the electroluminescent device organic layer, wherein the electroluminescent device organic layer is disposed on a side of the partition layer distal to the base substrate, the partition layer contacts the encapsulation layer and is disposed between the encapsulation layer and the base substrate, the partition layer is configured to divide the electroluminescent device organic layer into two discontinuous parts in the frame area, and the encapsulation layer is disposed between the two discontinuous parts.

17. A method for manufacturing a display panel that comprises a display area, a frame area, a base substrate, an insulating layer, a thin film transistor, a planarization layer, a first electrode layer, a pixel definition layer, a partition layer, an electroluminescent device organic layer, a second electrode layer, an encapsulation layer, an encapsulation glue and an encapsulation cover plate, comprising:
manufacturing the thin film transistor, the planarization layer, and the first electrode layer on the base substrate;
manufacturing the pixel definition layer and the partition layer on a side of the first electrode layer distal to the base substrate, wherein the partition layer is disposed in the frame area;
manufacturing the electroluminescent device organic layer and the second electrode layer on a side of the partition layer distal to the base substrate, wherein the partition layer corresponds to an edge of the electroluminescent device organic layer;
manufacturing the encapsulation layer on a side of the second electrode layer distal to the base substrate, wherein the partition layer contacts the encapsulation layer and is disposed between the encapsulation layer and the base substrate, the partition layer is configured to divide the electroluminescent device organic layer into two discontinuous parts in the frame area, and the encapsulation layer is disposed between the two discontinuous parts; and
completing encapsulation and performing a special-shaped cutting.

18. The method for manufacturing a display panel according to claim 17, wherein manufacturing the pixel definition layer and the partition layer on the side of the first electrode layer distal to the base substrate comprises: obtaining the pixel definition layer by coating a photoresist, curing, exposure, and development in sequence.

19. The method for manufacturing a display panel according to claim 18, wherein:
the partition layer comprises a first partition layer and a second partition layer, and the first partition layer and the second partition layer are adjacent to and contact each other in a direction parallel the base substrate;
an outer edge of the first partition layer inclines toward the electroluminescent device organic layer in the display area of the display panel in a direction from a level distal to the base substrate to a level close to the base substrate, and contacts the encapsulation layer;
an inner edge of the second partition layer is disposed in a vertical direction or in a direction parallel to the outer edge of the first partition layer, and contacts the electroluminescent device organic layer;
the outer edge of the first partition layer faces the frame area of the display panel, and the inner edge of the second partition layer faces the display area of the display panel; and
obtaining the pixel definition layer by coating a photoresist, curing, exposure, and development in sequence comprises: obstructing a positive photoresist in the frame area of the display panel during the exposure to obtain the second partition layer.

20. The method for manufacturing a display panel according to claim 19, wherein manufacturing the pixel definition layer and the partition layer on the side of the first electrode layer distal to the base substrate comprises: obtaining the first partition layer by coating a photoresist, curing, exposure, and development in sequence.
